(19) United States
(12) Patent Application Publication
(10) Pub. No.: US 2010/0258898 A1
(43) Pub. Date: Oct. 14, 2010

(54) PROCESS FOR FABRICATING AN ELECTRONIC DEVICE

(75) Inventor: Hacène Lahreche, Paris (FR)

Correspondence Address: EDWARDS ANGELL PALMER & DODGE LLP, P.O. BOX 55874, BOSTON, MA, 02205, US

(73) Assignee: S.O.I TEC Silicon on Insulator Technologies, Bernin (FR)

(21) Appl. No.: 12/787,840

(22) Filed: May 26, 2010

Related U.S. Application Data
(63) Continuation of application No. PCT/EP2008/066258, filed on Nov. 26, 2008.

(30) Foreign Application Priority Data
Nov. 27, 2007 (FR) 0759328

(51) Int. Cl. H01L 29/20; H01L 21/20; H01L 29/417

(52) U.S. Cl. 257/472; 438/481; 257/615; 257/E21.09; 257/E29.089; 257/E29.113

(57) ABSTRACT

An electronic device made of group III/N materials and a method of fabricating the device. The method includes growing by epitaxy on a substrate layer the following successive layers: a layer adapted to contain an electron gas, a barrier layer, and a surface layer. The method also includes an etching step performed on at least part of the surface layer. After the etching step, an epitaxial regrowth is performed to grow a covering layer on the etched surface layer. The material of the surface layer and the material of the covering layer include at least one Group III element and nitrogen.

### CROSS REFERENCE TO RELATED APPLICATIONS

This application is a continuation of and claims priority to International Patent Application No. PCT/EP2008/066258, filed Nov. 26, 2008, which claims priority to French Patent Application No. FR0759328, filed Nov. 27, 2007; the contents of each of these applications is incorporated herein by reference.

### BACKGROUND OF THE INVENTION

1. Field of the Invention

The present invention concerns an electronic device based on Group III/N materials, such as a rectifier or a field effect transistor, for example a High Electron Mobility Transistor (HEMT) or Metal Insulator Semiconductor (MIS). Group III/N materials are materials containing at least one Group III element and nitrogen.

2. Background of the Related Art

Etching processes are frequently used in fabricating electronic devices. FIG. 1C is a schematic illustration of an electronic device of a known type. This electronic device typically comprises, from its base to its surface: a substrate layer 1, a buffer layer 2, a channel layer 3, a barrier layer 4, a superficial layer 7, an ohmic contact electrode 5, a Schottky contact electrode 8 and a passivation layer 9. In the case of an HEMT transistor or a rectifier, the Schottky contact 8 is created directly in contact with the superficial layer 7, whereas in the case of an MIS transistor the Schottky contact 8 is deposited on the passivation layer 9.

The essential function of the substrate layer 1 is to ensure the rigidity of the device. The substrate layer 1 is covered with a buffer layer 2 and a layer adapted to contain an electron gas. These two layers may be distinct, in which case the layer adapted to contain the electron gas is generally referred to as the “channel layer” 3. However, it is also possible for these two layers to be combined, the buffer layer 2 being able, because of the heterojunction formed at the interface with the barrier layer 4, to allow an electron gas to flow. In this case, the channel is defined in the upper part of the buffer layer by the heterojunction formed with the barrier layer, without belonging to a layer distinct from the buffer layer.

The buffer layer 2 presents good crystallographic quality and appropriate properties for epitaxial growth of the other layers that will cover it. It therefore ensures the crystallographic transition between the substrate layer 1 and the layer formed on the buffer layer. The buffer layer 2 is constituted from a binary, ternary or quaternary alloy of Group III/N elements, such as GaN, for example.

If the buffer layer is also adapted to contain the electron gas, it must be made of a material having a band gap smaller than that of the barrier layer in order to allow the formation and flow of the electron gas therein.

If there exists a channel layer 3 which is distinct from the buffer layer 2, it is made of a Group III/N material which is based on gallium and may be a binary, ternary or quaternary alloy such as GaN, BGaN, InGaN, AIGaN or another alloy, having a band gap which is smaller than that of the barrier layer.

The role of the barrier layer 4 is to supply free electrons to the structure: it is referred to as the donor layer. The barrier layer 4 comprises a material comprised of a binary, ternary or quaternary alloy of Group III/N elements.

The choice of materials for the barrier layer and the layer adapted to contain the electron gas is free provided that the material of the latter always has a band gap which is smaller than that of the barrier layer.

The ohmic contact electrode 5 enables carriers to be injected or collected. In the case of a transistor, there are two ohmic contact electrodes: the source is the electrode that injects carriers into the structure, whereas the drain is the electrode that collects the carriers. In the case of a rectifier, there is only one ohmic contact electrode. The ohmic contact electrode 5 generally comprises a superposition of metal layers deposited on the upper surface or within the thickness of the barrier layer 4 in order to ensure good ohmic contact.

The barrier layer 4 may generally be covered, except at the position of the ohmic contact electrode, with a superficial layer 7. The superficial layer 7 avoids degradation of the structure and contributes to ensuring good Schottky contact with the Schottky contact electrode 8 which is deposited on it.

Finally, a passivation layer 9, composed for example of ZnO, Si3N4 or MgO, is applied to encapsulate the device. Passivation generally protects the surface of the semiconductor.

In the fabrication of such devices, use is frequently made of various etching steps starting from an initial structure represented in FIG. 1A. The initial structure includes the substrate layer 1 on which the buffer layer 2, the channel layer 3, the barrier layer 4 and the superficial layer 7 have been grown in succession.

Referring to FIG. 1 B, it is in particular known that, in order to isolate devices fabricated within the same wafer, an isolation etching can be carried out so as to form an isolation trench 10 between two devices. The depth of such an etching passes through the barrier layer and the channel layer to reach the isolating buffer layer.

It is also usual to etch the superficial layer 7 as far as the barrier layer 4 in order to form a trench 11 under the ohmic contact electrode so as to deposit the ohmic contact electrode 5 directly in contact with the barrier layer 4 or within the thickness of the latter.

It is also known that a trench 12 can be etched under the Schottky contact electrode 8. Such a trench, known as a “gate recess”, creates a geometrical effect in the superficial layer 7 which favors the maintenance of a high electron gas density by locally reducing the thickness of the superficial layer 7. The greater proximity of the Schottky contact electrode 8 and the channel layer 3 at the recess 12 provides better control of the electrons by the Schottky contact electrode.

The gate recess 12 under the Schottky contact electrode 8 may be formed not only in the superficial layer 7 but also in part of the barrier layer 4. This greater depth of the gate recess 12 further improves electron control because of greater proximity with the channel layer 3. Since, however, the barrier layer 4 constitutes the reservoir of free electrons of the channel layer 3, it must be of sufficient thickness to conserve a satisfactory electron gas density. It is therefore necessary to define a compromise between on the one hand the functional improvement provided by bringing the Schottky contact electrode 8 closer to the channel layer 3 and, on the other hand, the reduction in the electron gas density resulting from etching the barrier layer 4. It is considered in practice that the thickness of the barrier layer 4 must be greater than 2 nm.

However, the above-mentioned etching processes tend to create etched surfaces of which the condition is degraded relative to the condition of the surface of the material before etching. In particular, RIE (reactive ion etching), routinely used to form isolation trenches in devices, is particularly aggressive and damages the surface. Prior to etching, the surface of the layer is defined by an entanglement of atomic steps, as well as depressions linked to dislocations emerging from the crystal of the material. The destruction of this morphology by etching may result in the formation of surface defects and “surface states” which include electronic states localized at the surface acting as electron traps, and the etching may take place preferentially around the dislocations.

This results in particular in an increase in the density of crystal defects and electron traps, creating leakage currents at the interface between the superficial layer 7 and the passivation layer 9 and contributing to a diminution of the performance of the device. Surface damage due to etching is therefore a recurring problem in the fabrication of electronic devices.

One of the purposes of the invention is thus to provide a remedy for all these disadvantages by obtaining devices of which the performance is not degraded by the etching operations. A further purpose of the invention is to fabrication electronic devices in which leakage currents linked to etching are controlled and maintained below a certain level.

### BRIEF SUMMARY OF THE INVENTION

The invention offers a process for fabricating an electronic device made of Group III/N materials, including the epitaxial growth, on a substrate layer, of the following successive layers: a layer adapted to contain an electron gas; a barrier layer; and a surface layer. The process furthermore includes an etching step for at least part of the surface layer, said process being characterized in that, after the etching step, an epitaxial regrowth is performed in order to grow a covering layer on the etched surface layer and in that the material of the surface layer and the material of the covering layer include at least one Group III element and nitrogen.

Etching of at least part of the surface layer means etching of part of the thickness of the surface layer and/or part of the surface of that layer. The phrase “an epitaxial regrowth is performed in order to grow a covering layer on the etched surface layer” means that the covering layer covers the whole surface of the structure obtained on completion of the etching step, in other words: if the surface layer is only etched through part of its thickness, the covering layer covers the whole surface of the surface layer; if the surface layer is locally etched through its total thickness, such that one or more trenches are formed through which an underlying layer is exposed, the covering layer then covers not only the surface layer in the regions where it remains but also the underlying layer exposed in the trenches.

In a particular implementation, etching is also performed over part of the thickness of the barrier layer. During epitaxial regrowth, the covering layer can be grown and doped. In a preferred manner, etching of the surface layer is performed at the intended position for a Schottky contact electrode, so as to form a trench under the Schottky contact electrode. After the formation of the covering layer, the process advantageously includes the following steps: formation of a Schottky contact electrode in said trench; and formation of a passivation layer.

In an implementation variant, after the formation of the covering layer, there is etched, at the intended position of at least one ohmic contact electrode, a trench of which the depth is at least equal to the thickness of the covering layer and of the surface layer, so as to form the ohmic contact electrode on the barrier layer or within the thickness of the latter.

A further subject of the invention concerns an electronic device made of Group III/N materials comprising successively from its base to its surface: a substrate layer; a layer adapted to contain an electron gas; a barrier layer; and a surface layer over at least part of the surface of the barrier layer, the surface layer including at least one trench, the device being characterized in that the surface layer and said trench or trenches are covered by a covering layer of which the surface presents atomic steps separated by plateaus of which the width is greater than 2 nm and in that the material of the surface layer and the material of the covering layer include at least one Group III element and nitrogen.

The electronic device advantageously includes an ohmic contact electrode situated on the barrier layer or within the thickness of the latter. It may also include a Schottky contact electrode situated on the covering layer in a trench of which the depth is greater than or equal to the thickness of the surface layer. In a preferred embodiment, the surface layer is not doped and the covering layer is doped.

### BRIEF DESCRIPTION OF THE DRAWINGS

The invention will be better understood, and other advantages and features will be made clearer from the description below of several embodiments and examples of implementation, on the basis of the appended illustrations in which:

FIGS. 1A to 1C are views in cross section of an electronic device of a known type, illustrating the different steps in the fabrication of this device;

FIG. 2 is a photograph of the surface of an HEMT transistor; and

FIGS. 3A to 3D are views in cross section of an electronic device according to the invention, illustrating the different steps in the fabrication of this device.

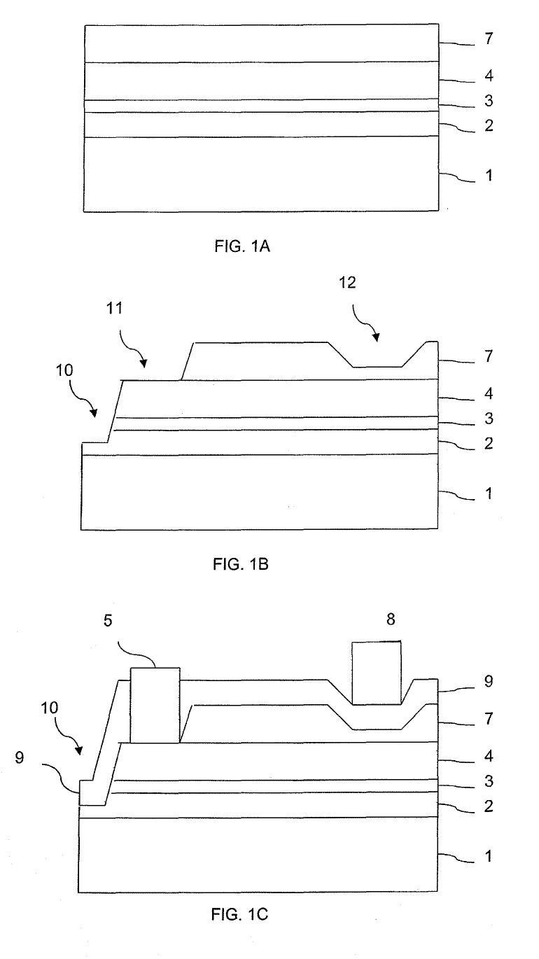

### DETAILED DESCRIPTION OF THE INVENTION

In an electronic device of the prior art, leakage currents appear at the interface between the superficial layer 7 and the passivation layer 9. These currents contribute to a diminution of the performance of the electronic device. Thus for an HEMT transistor, at a gate-source potential of —1 V for example, a reverse leakage of 10⁻⁹ to 10⁻⁸ A/mm has been observed (reference may be made in this regard to the publication by T Kikkawa, Fujitsu, Compound Semiconductor, July 2006, Vol. 12, No. 6, pages 23-25).

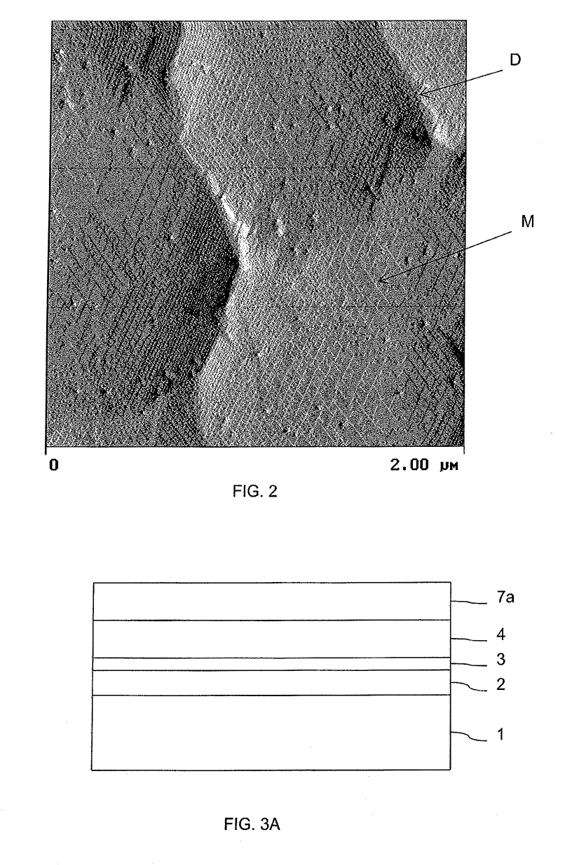

FIG. 2 is a photograph of the surface of an HEMT transistor fabricated by Molecular Beam Epitaxy (MBE), comprising a superficial layer of GaN on an AIGaN barrier layer and a GaN buffer layer. It may be observed in this photograph that the surface of the superficial layer presents an entanglement of atomic steps M and depressions D due to dislocations. The height of the steps M is of the order of 0.25 nm.

Leakage currents can be due to several phenomena, including interface states between the superficial layer and the passivation layer. For transistors based on GaAs, for example, it is known that the native oxide Ga₂O₃ formed from GaAs is unstable and causes the formation of traps at the interface.

Leakage currents can also be due to defects emerging from the crystal of the semiconductor material of the superficial layer. GaN, for example, typically presents 107 to 109 through thickness dislocations per cm². This produces surface depressions around which the stress varies locally. The combined effect of the surface morphology and the stress may have repercussions on the interface states with the passivation layer; the modification of potentials at the interface results in a change in the flow or the presence of trapped electrons;

Leakage currents can also be due to the etching (in particular RIE) processes, which are somewhat aggressive and can damage the surface. The destruction of the initial morphology of the surface as shown with reference to FIG. 2 may result in the formation of surface states and etching may occur preferentially around dislocations, generating new phenomena.

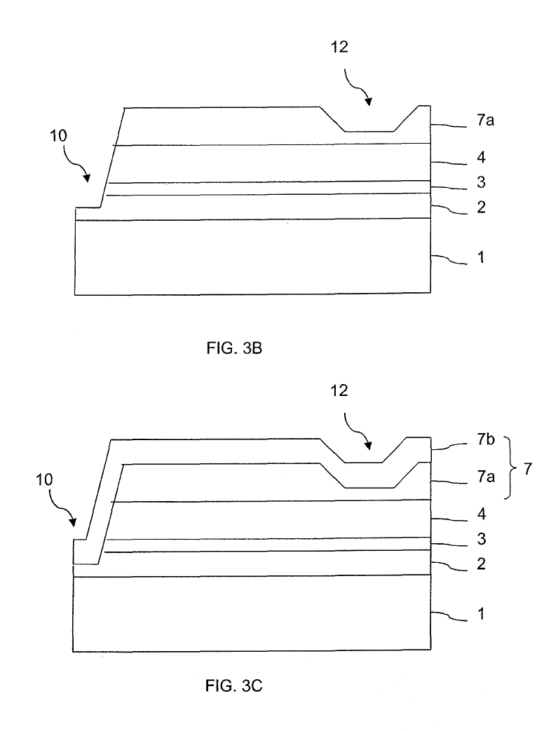

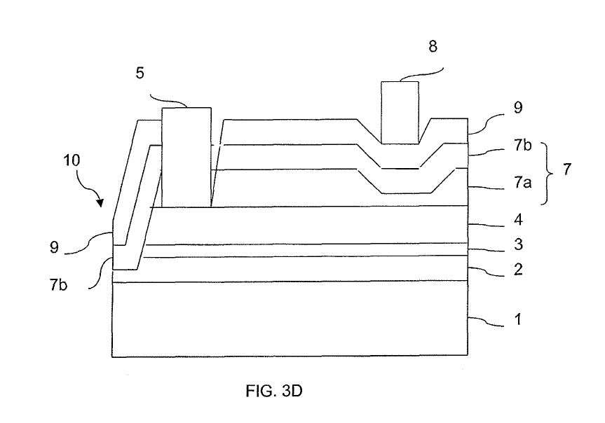

We shall first describe the initial structure of an electronic device according to the invention, from its base to its surface. Referring to FIG. 3A, the initial structure of this device comprises: a substrate layer 1, an optional buffer layer 2, a channel layer 3, a barrier layer 4 and a surface layer 7a. The substrate layer 1 may for example be made of silicon, SiC, GaN or AIN. The buffer layer 2 is formed from a material including nitrogen and at least one element from column III of the Periodic Table, for example GaN, AIGaN or AIN, BGaN or InGaN.

The channel layer 3 is formed from a material including nitrogen and at least one element from column III of the Periodic Table. However, if this material is identical to that of the buffer layer, it must be chosen such that its band gap is smaller than that of the barrier layer material in order to collect the electron gas. If the material is different from that of the buffer layer it is also necessary for its band gap to be smaller than that of the buffer layer material. The channel layer is preferably formed from GaN or InGaN. The barrier layer 4 is formed from a material including nitrogen and at least one element from column III of the Periodic Table and selected so that its band gap is greater than that of the channel layer material.

The surface layer 7a is also formed from a material including nitrogen and at least one element from column III of the Periodic Table. It is preferably made of GaN, AIGaN or InGaN, and must be chosen such that its band gap is smaller than that of the barrier layer material. The barrier layer 4 may for example be composed of AIGaN with an aluminum content of 50 to 70% of the elements in column III—the surface layer 7a may then be composed of AIGaN with an aluminum content of 20%. If the barrier layer 4 of AIGaN has an aluminum content of the order of 20%, the aluminum content of the surface layer 7a will preferably be less than or equal to 5%. The surface layer 7a has a thickness ranging from 1 to 10 nm.

The layers are grown by an epitaxy process (for example MBE (molecular beam epitaxy)). It should be recalled that epitaxy is a technique for the oriented growth, one with respect to the other, of two crystals possessing a certain number of common elements of symmetry in their crystal lattices. In addition to molecular beam epitaxy, there are various epitaxy techniques, for example metal organic chemical vapor deposition (MOCVD), low-pressure chemical vapor deposition (LPCVD) or hydride vapor phase epitaxy (HYPE).

Carried out on the initial structure represented in FIG. 3A, is, referring to FIG. 3B, at least one etch of the surface layer 7a, for example to form a trench 12 under the Schottky contact electrode, or to form an isolation trench 10. To this effect, the surface layer 7a is etched through all or part of its thickness.

The invention generally includes, after the etching operation on the epitaxial surface layer 7a, an epitaxial regrowth so as to form a covering layer 7b on the etched surface layer 7a, also covering the etched trench or trenches. Epitaxial regrowth is understood to mean that a second epitaxial step is performed after an intermediate technological step (such as etching or cleaning), itself implemented after a first epitaxy step. We specify that during this second epitaxy step the same material can be grown as in the first epitaxy step or a different material. In the same way, the epitaxial regrowth may use the same technique as the first step or a different technique. The surface layer 7a may for example be grown by MBE followed by the covering layer 7b by MOCVD.

The material of the layer 7b includes nitrogen and at least one element from column III of the Periodic Table: it may be identical to that of the layer 7a. Preferably, in order to improve the quality of the surface of the device, the material of the covering layer 7b has a lattice parameter near enough to that of the material of the surface layer 7a, for example the lattice parameter mismatch is less than 1%. This is because in case of a large difference between the lattice parameters of layers 7a and 7b, there is a risk of forming defects and/or cracks in the layer 7b if the latter exceeds a certain thickness. Furthermore, the temperatures of epitaxy of the materials of layers 7a and 7b are preferably not too different, in order to avoid stress due to the difference in thermal expansion coefficients, for example the difference is less than 400° C.

Referring to FIG. 3C, the covering layer 7b presents a constant thickness over the whole of its surface, such that its profile follows the profile of the surface layer 7a and of the trench or trenches on which it is formed. Its thickness ranges from 1 to 20 nm.

The epitaxial regrowth has the effect of reforming and repairing the crystal lattice of the surface layer 7a damaged by the etching process, which, at the interface between the covering layer 7b and the passivation layer, results in a limitation of the leakage currents.

It has indeed been observed that a surface damaged by etching is characterized by a succession of atomic steps separated by less than 2 nm. Between two adjacent steps, plateaus of which the width is less than 2 nm can therefore be defined. On the other hand, the epitaxial regrowth on this damaged surface permits the growth of a covering layer of which the surface includes atomic steps separated by at least 2 nm, i.e., plateaus with a width greater than 2 nm.

The size of the plateaus is directly linked to the presence of leakage currents at the interface between the superficial layer and the passivation layer. In effect, the smaller the plateaus, the greater the number of crystal defects, surface states and electron traps and the higher the probability of leakage currents forming.

There has thus been created, at the surface of the electronic device, a superficial layer 7 of which the structure is different according to the regions of the device. Specifically, in regions where the surface layer 7a has not been etched, the superficial layer 7 is formed from both the surface layer 7a and the covering layer 7b; this configuration typically occurs in the regions situated between the ohmic contact electrode 5 and the Schottky contact electrode 8. In regions where the surface layer 7a has been etched through part of its thickness, the superficial layer 7 is comprised of the residual surface layer and the covering layer 7b. Finally, in regions where the surface layer 7a has been etched through its whole thickness, or even more deeply into the barrier layer 4, the channel layer 3 or the buffer layer 2, the superficial layer 7 is constituted solely from the covering layer 7b. This situation typically arises in the trench for the Schottky contact (of which the etching depth is limited to part of the thickness of the barrier at most), or in the isolation trenches between devices (of which the etching stops at the surface or within the thickness of the isolating buffer layer).

The covering layer 7b formed by the epitaxial regrowth may be made of the same material as that of the surface layer 7a, but may be doped differently. The device may therefore have a undoped surface layer 7a but a covering layer 7b doped in the range 5×10¹⁷ atoms/cm³ to 5×10¹⁹ atoms/cm³ for example. The dopant used is typically silicon or germanium. The surface layer 7a may also be lightly doped in the range from 0 to 5×10¹⁷ atoms/cm³, which advantageously reduces the electron traps.

An exemplary embodiment may comprise a surface layer 7a doped at a concentration of 2×10¹⁵ atoms/cm³ and a more highly doped covering layer 7b with a concentration of 5×10¹⁸ atoms/cm³. After the formation of the covering layer 7b, a passivation layer 9 is preferably deposited which therefore covers the isolation trench 10 and the gate recess 12.

It may be noted that in certain regions of the device it may be preferable not to have a superficial layer. In particular, it is generally preferable to form the ohmic contact electrode 5 directly on the barrier layer 4 or within the thickness of the barrier layer which is rich in aluminum, since it is easier to obtain an alloy of the metal electrode with AIGaN than with the material (GaN) of the superficial layer, which improves the ohmic contact, for which a very low contact resistance is sought.

To this effect, after the formation of the covering layer 7b and the passivation layer 9, etching is performed at the planned position of the ohmic contact 5, of at least the passivation layer 9, the covering layer 7b and the surface layer 7a, until the barrier layer 4 is reached.

Referring to FIG. 3D, the ohmic contact electrode 5 is then deposited on the barrier layer 4 or within the thickness of the latter and the Schottky contact electrode 8 on the passivation layer 9 in the case of an MIS transistor. In the case of an HEMT transistor, the Schottky contact electrode 8 is deposited directly in contact with the covering layer 7b, the passivation layer being deposited subsequently.

The electronic device described above therefore presents improved performance relative to devices of the current technology, since leakage currents linked to the etching process are limited. It will be noted, however, that surface defects linked to the etching process are not the only cause of leakage currents. Part of the leakage currents is intrinsic, in other words, dependent on the nature of the materials. Leakage currents with causes other than etching may continue to exist within the device.

The invention applies advantageously to a rectifier which includes a Schottky contact electrode and an ohmic contact electrode or an HEMT or MIS field effect transistor which includes two ohmic contact electrodes (known as drain and source) and a Schottky contact electrode (known as a gate).

It will be apparent to those skilled in the art that the embodiments of the invention described above can be varied and modified in many ways without departing from the scope of the invention as defined by the appended claims and their equivalents.

The invention claimed is:

1. A process for fabricating an electronic device made of group III/N materials, the process comprising the steps of:
growing by epitaxy the following successive layers on a support layer: a layer adapted to contain an electron gas, a barrier layer, and a surface layer;
etching at least part of the surface layer; and
growing a covering layer on the etched surface layer using an epitaxial regrowth;
wherein the material of the surface layer and the material of the covering layer include at least one Group III element and nitrogen.

2. The process as claimed in claim 1, wherein the etching step includes the formation of at least one trench in the surface layer, the depth of the trench being greater than or equal to the thickness of the surface layer, and wherein the covering layer covers the surface layer and the trench.

3. The process as claimed in claim 1, wherein the etching step includes etching at least a part of the thickness of the barrier layer.

4. The process as claimed in claim 1, wherein during the epitaxial regrowth the covering layer is grown and doped.

5. The process as claimed in claim 1, wherein the etching of the surface layer is performed at the intended position for a Schottky contact electrode, so as to form a trench under the Schottky contact electrode.

6. The process as claimed in claim 5, further comprising the following steps after the formation of the covering layer:
forming a Schottky contact electrode in the trench; and
forming a passivation layer.

7. The process as claimed in claim 1, further comprising, after the formation of the covering layer, etching a trench at the planned position of at least one ohmic contact electrode, the trench having a depth that is at least equal to the combined thickness of the covering layer and the surface layer, so as to form the ohmic contact electrode on the barrier layer.

8. The process as claimed in claim 1, further comprising, after the formation of the covering layer, etching a trench at the planned position of at least one ohmic contact electrode, the trench having a depth that is at least equal to the combined thickness of the covering layer and the surface layer, so as to form the ohmic contact electrode within the thickness of the barrier layer.

9. An electronic device made of group III/N materials comprising successively from its base to its surface:
a substrate layer;
a layer adapted to contain an electron gas;
a barrier layer; and
a surface layer over at least part of the surface of the barrier layer;
wherein the surface layer includes at least one trench, and wherein the surface layer and the at least one trench are covered by a covering layer of which the surface presents atomic steps separated by plateaus having a width that is greater than 2 nm;
wherein the material of the surface layer and the material of the covering layer include at least one Group III element and nitrogen.

10. The electronic device as claimed in claim 9, further comprising an ohmic contact electrode situated on the barrier layer.

11. The electronic device as claim in claim 9, further comprising an ohmic contact electrode situated within the thickness of the barrier layer.

12. The electronic device as claimed in claim 9, further comprising a Schottky contact electrode situated on the covering layer in a trench having a depth that is greater than or equal to the thickness of the surface layer.

13. The electronic device as claimed in claim 9, wherein the surface layer is not doped and wherein the covering layer is doped.
